(19) United States
(12) Patent Application Publication
(10) Pub. No.: US 2018/0198458 A1
(43) Pub. Date: Jul. 12, 2018

(54) Verification, Validation, And Applications Support For Analog-To-Digital Converter Systems

(71) Applicant: Microchip Technology Incorporated, Chandler, AZ (US)

(72) Inventors: James E. Bartling, Chandler, AZ (US); Igor Wojewoda, Tempe, AZ (US)

(73) Assignee: Microchip Technology Incorporated, Chandler, AZ (US)

(21) Appl. No.: 15/864,724

(22) Filed: Jan. 8, 2018

Related U.S. Application Data
(60) Provisional application No. 62/443,321, filed on Jan. 6, 2017.

(51) Int. Cl. H03M 1/06

(52) U.S. Cl. CPC H03M 1/0617

(57) ABSTRACT

A microcontroller includes an analog-to-digital (ADC) controller circuit, an ADC converter circuit, and a multiplexer configured to multiplex output of the ADC converter circuit and a data source to the ADC controller circuit.

### PRIORITY

This application claims priority to U.S. Provisional Patent Application No. 62/443,321 filed Jan. 6, 2017, the contents of which are hereby incorporated in their entirety.

### TECHNICAL FIELD

The present disclosure relates to analog-to-digital converters (ADC) and, in particular, to verification, validation, and applications support for analog-to-digital converter systems

### BACKGROUND

Microcontrollers, processors, semiconductors, and other devices often use ADCs to convert analog data into a digital format. The data, once in a digital format, may be used for measurements, calculations, communication, or other suitable purposes.

### BRIEF DESCRIPTION OF THE DRAWINGS

FIG. 1 is an illustration of an example system including ADC use.

FIG. 2 is an illustration of an example system including verification, validation, and application support for ADCs, according to embodiments of the present disclosure.

### SUMMARY

Embodiments of the present disclosure may include an ADC. The ADC may include an ADC controller circuit, an ADC analog converter circuit, and a multiplexer configured to multiplex output of the ADC converter circuit and a first data source to the ADC controller circuit.

In combination with any of the above embodiments, the multiplexer may be further configured to further multiplex output of a second data source with the output of the ADC converter circuit and the first data source.

In combination with any of the above embodiments, the first data source may include emulated data.

In combination with any of the above embodiments, the multiplexer may be configured to select output of the first data source to the ADC controller circuit when the ADC converter is in a debug mode.

In combination with any of the above embodiments, in the debug mode the multiplexer may be configured to output data emulating response of the ADC converter circuit.

In combination with any of the above embodiments, the multiplexer may be configured to select output of the ADC converter circuit to the ADC controller circuit when the ADC converter is in a conversion mode.

In combination with any of the above embodiments, the multiplexer may be configured to select output of the ADC converter circuit to the ADC controller circuit when the ADC converter is in a conversion mode.

In combination with any of the above embodiments, the first data source may be a memory including data emulating operation of the ADC converter.

In combination with any of the above embodiments, the first data source may be an input for receiving externally emulated data emulating operation of the ADC converter.

In combination with any of the above embodiments, the ADC may further comprise an input to receive a determination of which of the ADC converter circuit and the first data source are to be routed to the ADC controller circuit.

Embodiments of the present disclosure may include a microcontroller, the microcontroller including any of the ADC embodiments described above.

Embodiments of the present disclosure may include a method, the method including steps and operations performed by any of the ADC or microcontroller embodiments described above.

### DETAILED DESCRIPTION

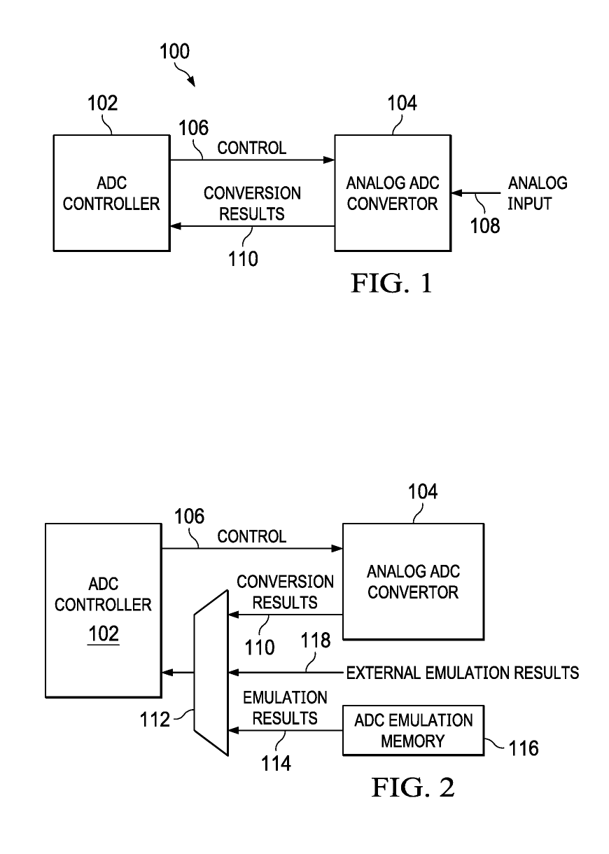

FIG. 1 is an illustration of an example system 100 including ADC use. System 100 may include an ADC controller 102 communicatively coupled to an ADC analog converter 104. ADC controller 102 may be implemented in any suitable manner, including by analog circuitry, digital circuitry, microcode, instructions for execution, or a combination of such elements. In one embodiment, ADC controller 102 may be implemented by digital logic interfacing with ADC analog converter 104. ADC analog converter 104 may be implemented by analog circuitry, digital circuitry, or a combination thereof. In one embodiment, ADC controller 102 and ADC analog converter 104 may form a single ADC. ADC controller 102 and ADC analog converter 104 may be implemented within a single die, semiconductor device, package, peripheral, or other electronic device. ADC controller 102 may instruct ADC analog converter 104 to close or open switches, control the timing and sequencing of signal acquisition, and perform captures of the data so that the data may be used and presented to a central processing unit.

The system 100 for an ADC may be implemented in, for example, a microcontroller, processor, board, chip, package, or any other semiconductor device. Many instances of system 100 may exist in parallel with each other. In some embodiments, multiple instances of ADC analog convert 104 may exist in parallel and controlled by a single ADC controller 102.

ADC controller 102 may receive instructions to perform sampling of analog values from a microcontroller or other entity in which system 100 is resident. The instructions may define how many samples are to be taken, timing of how the samples are to be taken, granularity of the sampling, resolution of bits to be used in the sampling, an input range, or other suitable parameters of operation. ADC controller 102 may be configured to, based upon these parameters, issue control commands 106 to ADC converter 104. The parameters and the commands may be implemented in any suitable manner. For example, the parameters may be set through function calls, setting registers, or other suitable mechanisms. These may include parameters issued by software to ADC controller 102. The commands may be issued through, for example, digital enable signals to turn or off various circuitry to operate ADC converter 104.

When ADC analog converter 104 receives control commands 106, ADC analog converter may perform conversion of analog input 108. Analog input 108 may be converted into any suitable data format and sent to ADC controller 102 in conversion results 110. The data format may require further processing, buffering, filtering, or other action in ADC controller 102. Analog converter 104 may receive control commands 106 though, for example, control pins. Control commands 106 may specify, for example, whether or not to enable conversion, how to make the conversion, a resolution of acquisition including how many bits are to be used, how fast or often to make the conversion, the digital format to which conversion should be made, and other suitable operating parameters. ADC analog converter may, once enabled, continually or periodically provide digital data to ADC controller 102. ADC controller 102 may format the data and provide it to other parts of an entity including system 100 for use of the digital data. Data produced by ADC controller 102 may be in the form of any suitable word format, such as 8-bit, 10-bit, or 12-bit words for representing the converted value in binary format.

In many cases, full operation of a system with an ADC requires results to be provided by the ADC. In some solutions, testing system 100 without ADC controller 102 is not possible. Furthermore, when using other solutions with an ADC convertor it can be difficult to generate a repeatable data set leading to subjective results during testing; when testing such an ADC multiple times, the ADC will not be yielding identical conversion values. Embodiments of the present disclosure may, in contrast, allow debugging of systems such as switched mode power systems (SMPS) or motor control as system tests may be performed.

Embodiments of the present disclosure may enable generation of repeatable data sets through a part of system 100. System 100 may be tested through acquisition of repeated, identical data in a test or safe environment before acquiring real data. In addition, system 100 may be used when developing a design or a new ADC controller. In such a case, system 100 may be used to emulate and debug the new ADC controller when the analog ADC core is not present, or when a reliable input signal source is unavailable. Embodiments of the present disclosure may be applied to allow end users and developers to provide simulated stimulus to the digital system while the system may not be fully implemented yet.

FIG. 2 is another illustration of system 100 configured to operate an ADC in a debug or emulation mode, according to embodiments of the present disclosure. As shown, system 100 may enable generation of repeatable data sets. The debug or emulation mode may be enabled by instructions or parameters issued to system 100, such as through a register setting. During debug or emulation mode, ADC analog converter 104 might not be available, reliable, or known inputs to ADC analog converter 104 might not be available.

In a debug or emulation mode, a digital source of data for debug of the system may be included. Any suitable source of data may be used. The data may be in digital format, in the manner in which ADC analog converter 104 was to otherwise provide data to the controller based upon command control instructions as shown in FIG. 1. For example, digital data may be provided from external sources 118. These may include external emulation results routed internally or externally to system 100 through, for example, control pins. In another example, digital data may be provided from memory 116, storing example, debug, or emulation data. These emulation results may be provided in results 114.

In one embodiment, a multiplexer 112 may be used to select which of the digital sources or ADC analog converter 104 will be used to provide digital data or results to ADC controller 102. Any other suitable mechanism for selecting data may be used. Multiplexer 112 may be inserted into the data path between ADC analog converter 104 and ADC controller 102. Multiplexer 112 may select data from any suitable data source, such as an on-chip memory, a bus, a memory interface, or an external data interface. This may be useful in debug situations such applications as capacitance touch. The data provided from memory or the external data source may be known and repeatable, and may include a series of test data vectors.

In a normal operation mode for ADC conversion, multiplexer 112 may be configured to select input from ADC analog converter 104 to route to ADC controller 102, representing a conversion of analog inputs 108. In a debug operation mode, multiplexer 112 may be configured to select input from other data sources such as memory 116 or external emulation results 118, representing an emulation of a conversion of analog inputs 108.

Designers of ADCs may design the ADCs within larger subsystems using register-transfer level (RTL) abstraction or another suitable hardware description language (HDL). The design may change as revisions are made. Upon revisions of the abstraction of the larger subsystem or of system 100 including an ADC, a known data set may be used to generate digital data in place of ADC analog converter 104 to ADC controller 102 and the rest of system 100 or the larger entity. The known data set may be configured to generate a known response, and the response from the actual circuit may be checked for accuracy. Consequently, validation may be accomplished more accurately and with less intervention. Users may modify the abstraction and provide a known stimulus from debug or emulation results, holding system 100 in debug or emulation mode. The corresponding results as reported through ADC controller 102 may be observed. In systems handling high power, changes to the abstraction can be validated before power is applied, thus reducing risk of damage. Lower cost of development may result from design to customer implementation. Absolute testing with known data sets may be possible, with less risk of damaging situations.

As discussed above, system 100 may be included in any suitable device, such as a controller, processor, or other semiconductor device. System 100 may be controlled by such a device. Moreover, a debug mode for system 100 may be enabled or disabled by such a device or by a test rack or test system testing system 100. The debug mode may be enabled through a command, bit, instruction, register setting, or other suitable mechanism. In one embodiment, ADC controller 102 may be unaware of whether the debug mode is employed. In another embodiment, ADC controller 102 may be aware of whether the debug mode is employed. The debug mode may be employed by selecting multiplexer 112 to use data input from a source other than ADC analog converter 104. The device or test system hosting system 100 may make appropriate connections for such a source other than ADC analog converter 104, such as handling external routing of data pins to the multiplexer so that the data is available.

In one embodiment, multiplexer 112 may be available to be enabled in a design or test phase of development. Subsequently, the multiplexer might be made unavailable when system 100 is deployed. This may be performed through any suitable locking mechanism, or by not exposing the ability to enable the debug mode after production of a final version of system 100. A bit or other value may be hard-written to a register value. In another embodiment, multiplexer 112 may be available to be enabled at any time, and thus debug mode may be available.

Given choices of data with which to connect to ADC controller 102, multiplexer 112 may route an identified source according to the same control mechanisms that enabled multiplexer 112. For example, the command signals to enable multiplexer 112 may specify which data source to use, and for how long. The format, data width, resolution, and baud rate of the data provided by the source of the data may be set according to instructions, command, and control signals issued by ADC controller 102 or external to ADC controller 102 if ADC controller 102 is unaware of the mode of operation.

The present disclosure has been described in terms of one or more embodiments, and it should be appreciated that many equivalents, alternatives, variations, and modifications, aside from those expressly stated, are possible and within the scope of the disclosure. While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein.

1. An analog-to-digital (ADC) converter, comprising:
an ADC controller circuit;
an ADC converter circuit; and
a multiplexer configured to multiplex output of the ADC converter circuit and a first data source to the ADC controller circuit.

2. The ADC of claim 1, wherein the multiplexer is further configured to further multiplex output of a second data source with the output of the ADC converter circuit and the first data source.

3. The ADC of claim 1, wherein the first data source includes emulated data.

4. The ADC of claim 1, wherein the multiplexer is configured to select output of the first data source to the ADC controller circuit when the ADC converter is in a debug mode.

5. The ADC of claim 4, wherein in the debug mode the multiplexer may be configured to output data emulating response of the ADC converter circuit.

6. The ADC of claim 1, wherein the multiplexer is configured to select output of the ADC converter circuit to the ADC controller circuit when the ADC converter is in a conversion mode.

7. The ADC of claim 6, wherein the multiplexer is configured to select output of the ADC converter circuit to the ADC controller circuit when the ADC converter is in a conversion mode.

8. The ADC of claim 1, wherein the first data source is a memory including data emulating operation of the ADC converter.

9. The ADC of claim 1, wherein the first data source is an input for receiving externally emulated data emulating operation of the ADC converter.

10. The ADC of claim 1, further comprising an input to receive a determination of which of the ADC converter circuit and the first data source are to be routed to the ADC controller circuit.

11. A microcontroller, comprising:
an analog-to-digital (ADC) controller circuit;
an ADC converter circuit; and
a multiplexer configured to multiplex output of the ADC converter circuit and a first data source to the ADC controller circuit.

12. The microcontroller of claim 11, wherein the multiplexer is further configured to further multiplex output of a second data source with the output of the ADC converter circuit and the first data source.

13. The microcontroller of claim 11, wherein the first data source includes emulated data.

14. The microcontroller of claim 11, wherein the multiplexer is configured to select output of the first data source to the ADC controller circuit when the ADC converter is in a debug mode.

15. The microcontroller of claim 14, wherein in the debug mode the multiplexer may be configured to output data emulating response of the ADC converter circuit.

16. The microcontroller of claim 11, wherein the multiplexer is configured to select output of the ADC converter circuit to the ADC controller circuit when the ADC converter is in a conversion mode.

17. The microcontroller of claim 16, wherein the multiplexer is configured to select output of the ADC converter circuit to the ADC controller circuit when the ADC converter is in a conversion mode.

18. The microcontroller of claim 11, wherein the first data source is a memory including data emulating operation of the ADC converter.

19. The microcontroller of claim 11, wherein the first data source is an input for receiving externally emulated data emulating operation of the ADC converter.

20. The microcontroller of claim 11, further comprising an input to receive a determination of which of the ADC converter circuit and the first data source are to be routed to the ADC controller circuit.
